(19) United States
(12) Patent Application Publication
(10) Pub. No.: US 2006/0115590 A1
(43) Pub. Date: Jun. 1, 2006

(54) Method and system for performing in-situ cleaning of a deposition system

(75) Inventors: Kenji Suzuki, Guilderland, NY (US); Gerrit J. Leusink, Saltpoint, NY (US); Fenton R. McFeely, Ossining, NY (US); Sandra G. Malhotra, Beacon, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: Tokyo Electron Limited; International Business Machines Corporation

(21) Appl. No.: 10/998,394

(22) Filed: Nov. 29, 2004

(51) Int. Cl. C23C 16/00

(52) U.S. Cl. 427/248.1; 118/715; 118/726

(57) ABSTRACT

A method for depositing metal layers, such as Ruthenium, on semiconductor substrates by a thermal chemical vapor deposition (TCVD) process includes introducing a metal carbonyl precursor in a deposition system, and depositing a metal layer from the metal carbonyl on a substrate. The TCVD process utilizes a short residence time for the gaseous species in the processing zone above the substrate to form a low-resistivity metal layer. In the deposition system, the metal carbonyl is evaporated in a solid precursor evaporation system, and the precursor vapor is transported to the process chamber via a vapor delivery system. Further, an in-situ cleaning system is coupled to the vapor delivery system in order to perform periodic cleaning of the deposition system. Periodic in-situ cleaning permits achieving a greater deposition rate by operating the deposition system at higher temperature where precursor vapor can decompose and potentially deposit on surfaces of the deposition system.

### BACKGROUND OF THE INVENTION

1. Field of the Invention

The present invention relates to a method and system for thin film deposition, and more particularly to a method and system for high rate thin film deposition, wherein periodic in-situ cleaning is performed to remove precursor and deposition residue from both the process chamber and the vapor delivery system.

2. Description of Related Art

The introduction of copper (Cu) metal into multilayer metallization schemes for manufacturing integrated circuits can necessitate the use of diffusion barriers/liners to promote adhesion and growth of the Cu layers and to prevent diffusion of Cu into the dielectric materials. Barriers/liners that are deposited onto dielectric materials can include refractive materials, such as tungsten (W), molybdenum (Mo), and tantalum (Ta), that are non-reactive and immiscible in Cu, and can offer low electrical resistivity. Current integration schemes that integrate Cu metallization and dielectric materials can require barrier/liner deposition processes at substrate temperature between about 400° C. and about 500° C., or lower.

For example, Cu integration schemes for technology nodes less than or equal to 130 nm currently utilize a low dielectric constant (low-k) inter-level dielectric, followed by a physical vapor deposition (PVD) TaN layer and Ta barrier layer, followed by a PVD Cu seed layer, and an electrochemical deposition (ECD) Cu fill. Generally, Ta layers are chosen for their adhesion properties (i.e., their ability to adhere on low-k films), and Ta/TaN layers are generally chosen for their barrier properties (i.e., their ability to prevent Cu diffusion into the low-k film).

As described above, significant effort has been devoted to the study and implementation of thin transition metal layers as Cu diffusion barriers, these studies including such materials as chromium, tantalum, molybdenum and tungsten. Each of these materials exhibits low miscibility in Cu. More recently, other materials, such as ruthenium (Ru) and rhodium (Rh), have been identified as potential barrier layers since they are expected to behave similarly to conventional refractory metals. However, the use of Ru or Rh can permit the use of only one barrier layer, as opposed to two layers, such as Ta/TaN. This observation is due to the adhesive and barrier properties of these materials. For example, one Ru layer can replace the Ta/TaN barrier layer. Moreover, current research is finding that the one Ru layer can further replace the Cu seed layer, and bulk Cu fill can proceed directly following Ru deposition. This observation is due to good adhesion between the Cu and the Ru layers.

Conventionally, Ru layers can be formed by thermally decomposing a ruthenium-containing precursor, such as a ruthenium carbonyl precursor, in a thermal chemical vapor deposition (TCVD) process. Material properties of Ru layers that are deposited by thermal decomposition of metal-carbonyl precursors (e.g., Ru₃(CO)₁₂) can deteriorate when the substrate temperature is lowered to below about 400° C. As a result, an increase in the (electrical) resistivity of the Ru layers and poor surface morphology (e.g., the formation of nodules) at low deposition temperatures, has been attributed to increased incorporation of CO reaction by-products into the thermally deposited Ru layers. Both effects can be explained by a reduced CO desorption rate from the thermal decomposition of the ruthenium-carbonyl precursor at substrate temperatures below about 400° C.

Additionally, the use of metal-carbonyls, such as ruthenium carbonyl, can lead to poor deposition rates due to their low vapor pressure and the transport issues associated therewith. Overall, the inventor has observed that current deposition systems suffer from such a low rate, making the deposition of such metal films impractical.

### SUMMARY OF THE INVENTION

The present invention provides a method and system for depositing a metal film from a metal-carbonyl precursor in a deposition system, wherein periodic cleaning of the deposition system, including the process chamber and the vapor delivery system, is performed using an in-situ cleaning system. To that end, a deposition system is provided that comprises a process chamber, a metal precursor evaporation system, a vapor delivery system, a carrier gas supply system, and an in-situ cleaning system. The process chamber has a substrate holder configured to support the substrate and heat the substrate, a vapor distribution system configured to introduce metal precursor vapor above the substrate, and a pumping system configured to evacuate the process chamber. The metal precursor evaporation system is configured to evaporate a metal precursor. The vapor delivery system has a first end coupled to an outlet of the metal precursor evaporation system and a second end coupled to an inlet of the vapor distribution system of the process chamber. The carrier gas supply system is coupled to at least one of the metal precursor evaporation system or the vapor delivery system, or both, to supply a carrier gas for transporting the metal precursor vapor through the vapor delivery system to the inlet of the vapor distribution system. The in-situ cleaning system is coupled to the vapor delivery system adjacent to the metal precursor evaporation system to provide a cleaning composition to the vapor delivery system and the process chamber to remove residue formed on interior surfaces of the vapor delivery system and the process chamber.

The present invention further provides a method for depositing a refractory metal film on a substrate with periodic in-situ cleaning of the vapor delivery system and process chamber to allow for a higher deposition rate. To that end, the method comprises depositing the refractory metal film on a desired number of substrates using a deposition system configured to perform thermal chemical vapor deposition (TCVD) from a metal precursor; and cleaning the deposition system, in particular the vapor delivery system and process chamber, following deposition of the refractory metal film on the desired number of substrates by introducing a cleaning composition formed in an in-situ cleaning system to the vapor delivery system of the deposition system adjacent the metal precursor evaporation system and flowing the cleaning composition through the vapor delivery system and into the process chamber.

### BRIEF DESCRIPTION OF THE DRAWINGS

In the accompanying drawings:

FIG. 1 depicts a schematic view of a deposition system according to an embodiment of the invention;

FIG. 2 depicts a schematic view of a deposition system according to another embodiment of the invention; and

FIG. 3 illustrates a method of depositing a metal film on a substrate according to an embodiment of the invention.

### DETAILED DESCRIPTION OF PREFERRED EMBODIMENTS

In the following description, in order to facilitate a thorough understanding of the invention and for purposes of explanation and not limitation, specific details are set forth, such as a particular geometry of the deposition system and descriptions of various components. However, it should be understood that the invention may be practiced in other embodiments that depart from these specific details.

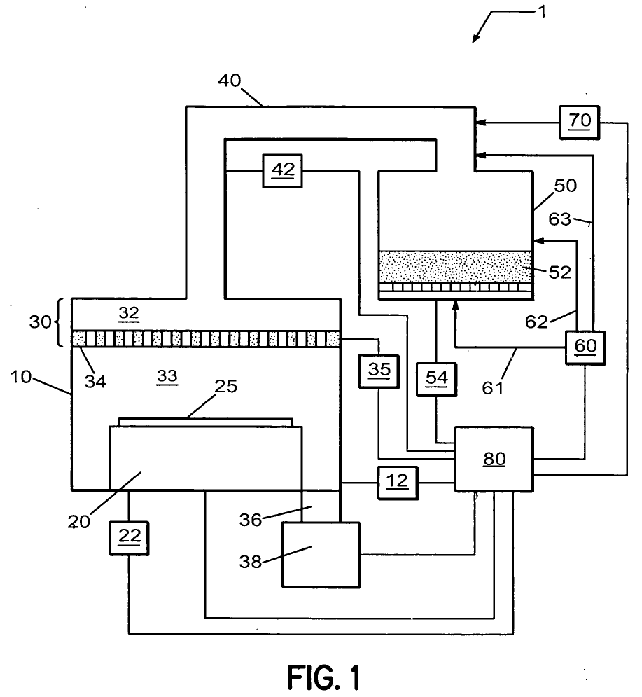

Referring now to the drawings, wherein like reference numerals designate identical or corresponding parts throughout the several views, FIG. 1 illustrates a deposition system 1 for depositing a metal film, such as a ruthenium (Ru) or a rhenium (Re) film, on a substrate according to one embodiment. The deposition system 1 comprises a process chamber 10 having a substrate holder 20 configured to support a substrate 25, upon which the metal film is formed. The process chamber 10 is coupled to a metal precursor evaporation system 50 via a vapor delivery system 40.

The process chamber 10 is further coupled to a vacuum pumping system 38 through a duct 36, wherein the pumping system 38 is configured to evacuate the process chamber 10, vapor delivery system 40, and metal precursor evaporation system 50 to a pressure suitable for forming the metal film on substrate 25, and suitable for evaporation of the metal precursor 52 in the metal precursor evaporation system 50.

Referring still to FIG. 1, the metal precursor evaporation system 50 is configured to store a metal precursor 52, and heat the metal precursor 52 to a temperature sufficient for evaporating the metal precursor 52, while introducing vapor phase metal precursor to the vapor delivery system 40. The metal precursor 52 can, for example, comprise a solid metal precursor. Additionally, for example, the metal precursor can include a metal-carbonyl. For instance, the metal precursor 52 can include ruthenium carbonyl (Ru₃(CO)₁₂), or rhenium carbonyl (Re₂(CO)₁₀). Additionally, for instance, the metal precursor 52 can be W(CO)₆, Mo(CO)₆, Co₂(CO)₈, Rh₄(CO)₁₂, Cr(CO)₆, or Os₃(CO)₁₂.

In order to achieve the desired temperature for evaporating the metal precursor 52 (or subliming the solid metal precursor), the metal precursor evaporation system 50 is coupled to an evaporation temperature control system 54 configured to control the evaporation temperature. For instance, the temperature of the metal precursor 52 is generally elevated to approximately 40-45° C. in conventional systems in order to sublime the ruthenium carbonyl. At this temperature, the vapor pressure of the ruthenium carbonyl, for instance, ranges from approximately 1 to approximately 3 mTorr. As the metal precursor is heated to cause evaporation (or sublimation), a carrier gas can be passed over the metal precursor, by the metal precursor, or through the metal precursor, or any combination thereof. The carrier gas can include, for example, an inert gas, such as a noble gas (i.e., He, Ne, Ar, Kr, Xe), or a monoxide, such as CO, for use with metal-carbonyls, or a mixture thereof. For example, a carrier gas supply system 60 is coupled to the metal precursor evaporation system 50, and it is configured to, for instance, supply the carrier gas beneath the metal precursor 52 via feed line 61, or above the metal precursor 52 via feed line 62. In another example, carrier gas supply system 60 is coupled to the vapor delivery system 40 and is configured to supply the carrier gas to the vapor of the metal precursor 52 vi feed line 63 as or after it enters the vapor delivery system 40. Although not shown, the carrier gas supply system 60 can comprise a gas source, one or more control valves, one or more filters, and a mass flow controller. For instance, the flow rate of carrier gas can range from approximately 5 sccm (standard cubic centimeters per minute) to approximately 1000 sccm. For example, the flow rate of carrier gas can range from about 10 sccm to about 200 sccm. By way of further example, the flow rate of carrier gas can range from about 20 sccm to about 100 sccm.

Downstream from the metal precursor evaporation system 50, the metal precursor vapor flows with the carrier gas through the vapor delivery system 40 until it enters a vapor distribution system 30 coupled to the process chamber 10. The vapor delivery system 40 can be coupled to a vapor line temperature control system 42 in order to control the vapor line temperature and prevent decomposition of the metal precursor vapor as well as condensation of the metal precursor vapor. For example, the vapor line temperature can be set to a value approximately equal to or greater than the evaporation temperature. Additionally, for example, the vapor delivery system 40 can be characterized by a high conductance in excess of about 50 liters/second.

Referring again to FIG. 1, the vapor distribution system 30, coupled to the process chamber 10, comprises a plenum 32 within which the vapor disperses prior to passing through a vapor distribution plate 34 and entering a processing zone 33 above substrate 25. In addition, the vapor distribution plate 34 can be coupled to a distribution plate temperature control system 35 configured to control the temperature of the vapor distribution plate 34. For example, the temperature of the vapor distribution plate can be set to a value approximately equal to the vapor line temperature. However, it may be less, or it may be greater.

Once metal precursor vapor enters the processing zone 33, the metal precursor vapor thermally decomposes upon adsorption at the substrate surface due to the elevated temperature of the substrate 25, and the metal film is formed on the substrate 25. The substrate holder 20 is configured to elevate the temperature of substrate 25 by virtue of the substrate holder 20 being coupled to a substrate temperature control system 22. For example, the substrate temperature control system 22 can be configured to elevate the temperature of substrate 25 up to approximately 500° C. In one embodiment, the substrate temperature can range from about 100° C. to about 500° C. In another embodiment, the substrate temperature can range from about 300° C. to about 400° C. Additionally, process chamber 10 can be coupled to a chamber temperature control system 12 configured to control the temperature of the chamber walls.

As described above, for example, conventional systems have contemplated operating the metal precursor evaporation system 50, as well as the vapor delivery system 40, within a temperature range of approximately 40-45° C. for ruthenium carbonyl in order to limit metal vapor precursor decomposition and metal vapor precursor condensation. For example, ruthenium carbonyl precursor can decompose at elevated temperatures to form by-products, such as those illustrated below:
Ru₃(CO)₁₂*(ad) [symbol] RU₃(CO)ₓ*(ad)+(12−x)CO(g) (1)
or,
Ru₃ (CO)ₓ*(ad) [symbol] 3Ru(s)+xCO(g) (2)
wherein these by-products can adsorb (ad), i.e., condense, on the interior surfaces of the deposition system 1, in particular, on the surfaces within the vapor delivery system 40 and the process chamber 10. The accumulation of material on these surfaces can cause problems from one substrate to the next, such as process repeatability. Alternatively, for example, ruthenium carbonyl precursor can condense at depressed temperatures to cause recrystallization, viz.
Ru₃ (CO)₁₂ (g) [symbol] Ru₃ (CO)₁₂*(ad) (3).

However, within such systems having a small process window, the deposition rate becomes extremely low, due in part to the low vapor pressure of ruthenium carbonyl. For instance, the deposition rate can be as low as approximately 1 Angstrom per minute. Therefore, according to one embodiment, the evaporation temperature is elevated to be greater than or equal to approximately 40° C. Alternatively, the evaporation temperature is elevated to be greater than or equal to approximately 50° C. In one exemplary embodiment of the present invention, the evaporation temperature is elevated to be greater than or equal to approximately 60° C. In a further exemplary embodiment, the evaporation temperature is elevated to range from approximately 60 to 150° C., for example from approximately 60-90° C. The elevated temperature increases the evaporation rate due to the higher vapor pressure (e.g., nearly an order of magnitude larger) and, hence, it is expected by the inventors to increase the deposition rate.

In addition to increasing the deposition rate, the elevated temperature also increases the rate of accumulation of residue on the surfaces of the deposition system 1, in particular on the surfaces within the vapor delivery system 40 and the process chamber 10. Thus, after a desired number of substrates have been processed in process chamber 10 to deposit the thin film, the deposition system 1 is cleaned using an in-situ cleaning system 70 coupled to the vapor delivery system 40 adjacent the metal precursor evaporation system 50, as shown in FIG. 1. By feeding a cleaning composition into the vapor delivery system 40 at or near the location where the vapor first enters the vapor delivery system 40, a complete cleaning of the delivery lines may be achieved. The cleaning composition is then fed into the process chamber 10, and additionally, if desired (although not shown), the in-situ cleaning system 70 can be further coupled to the process chamber 10 to feed fresh cleaning composition to the process chamber 10. Per a frequency determined by the operator, the in-situ cleaning system 70 can perform routine periodic cleanings of the deposition system 1 in order to remove accumulated residue on interior surfaces of deposition system 1. The in-situ cleaning system 70 can, for example, comprise a radical generator configured to introduce chemical radical capable of chemically reacting and removing such residue. Additionally, for example, the in-situ cleaning system 70 can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), O₃, XeF₂, CIF₃, or C₃F₈ (or, more generally, CₓF_{y}), respectively. The radical generator can include an Astron® reactive gas generator, commercially available from MKS Instruments, Inc., ASTeX® Products (90 Industrial Way, Wilmington, Mass. 01887).

During operation of a cleaning process, several parameters can be set and optimized for cleaning performance. For example, the operator can set, monitor, adjust, or control the flow rate of the cleaning composition, the vapor line temperature, the temperature of the vapor distribution plate, the temperature of the substrate holder (or “dummy” substrate), the temperature of the process chamber, the pressure in the process chamber, or any combination thereof.

Still referring the FIG. 1, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor delivery system 40, the metal precursor evaporation system 50, the carrier gas supply system 60, and the in-situ cleaning system 70.

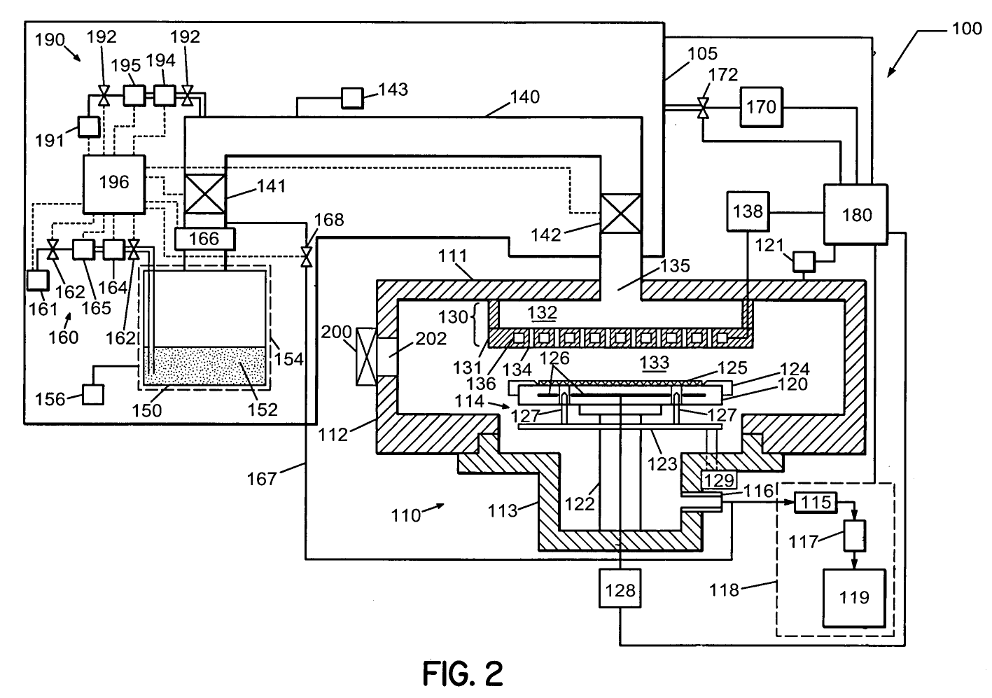

In yet another embodiment, FIG. 2 illustrates a deposition system 100 for depositing a metal film, such as a ruthenium (Ru) or a rhenium (Re) film, on a substrate. The deposition system 100 comprises a process chamber having a substrate holder 120 configured to support a substrate 125, upon which the metal film is formed. The process chamber 110 is coupled to a precursor delivery system 105 having metal precursor evaporation system 150 configured to store and evaporate a metal precursor 152, and a vapor delivery system 140 configured to transport the metal precursor 152.

The process chamber 110 comprises an upper chamber section 111, a lower chamber section 112, and an exhaust chamber 113. An opening 114 is formed within lower chamber section 112, where bottom section 112 couples with exhaust chamber 113.

Referring still to FIG. 2, substrate holder 120 provides a horizontal surface to support substrate (or wafer) 125, which is to be processed. The substrate holder 120 can be supported by a cylindrical support member 122, which extends upward from the lower portion of exhaust chamber 113. An optional guide ring 124 for positioning the substrate 125 on the substrate holder 120 is provided on the edge of substrate holder 120. Furthermore, the substrate holder 120 comprises a heater 126 coupled to substrate holder temperature control system 128. The heater 126 can, for example, include one or more resistive heating elements. Alternately, the heater 126 can, for example, include a radiant heating system, such as a tungsten-halogen lamp. The substrate holder temperature control system 128 can include a power source for providing power to the one or more heating elements, one or more temperature sensors for measuring the substrate temperature or the substrate holder temperature, or both, and a controller configured to perform at least one of monitoring, adjusting, or controlling the temperature of the substrate or substrate holder.

During processing, the heated substrate 125 can thermally decompose a metal-carbonyl precursor 152, and enable deposition of a metal layer on the substrate 125. According to one embodiment, the metal precursor includes a solid metal precursor. According to another embodiment, the metal precursor includes a metal-carbonyl precursor. According to yet another embodiment, the metal precursor 152 can be a ruthenium-carbonyl precursor, for example Ru₃(CO)₁₂. According to yet another embodiment of the invention, the metal precursor 152 can be a rhenium carbonyl precursor, for example Re₂(CO)₁₀. As will be appreciated by those skilled in the art of thermal chemical vapor deposition, other ruthenium carbonyl precursors and rhenium carbonyl precursors can be used without departing from the scope of the invention. In yet another embodiment, the metal precursor 152 can be W(CO)₆, Mo(CO)₆, Co₂(CO)₈, Rh₄(CO)₁₂, Cr(CO)₆, or Os₃(CO)₁₂, or the like. The substrate holder 120 is heated to a pre-determined temperature that is suitable for depositing the desired Ru, Re or other metal layer onto the substrate 125. Additionally, a heater (not shown), coupled to a chamber temperature control system 121, can be embedded in the walls of process chamber 110 to heat the chamber walls to a pre-determined temperature. The heater can maintain the temperature of the walls of process chamber 110 from about 40° C. to about 150° C., for example from about 40° C. to about 80° C. A pressure gauge (not shown) is used to measure the process chamber pressure.

Also shown in FIG. 2, a vapor distribution system 130 is coupled to the upper chamber section 111 of process chamber 110. Vapor distribution system 130 comprises a vapor distribution plate 131 configured to introduce precursor vapor from vapor distribution plenum 132 to a processing zone 133 above substrate 125 through one or more orifices 134.

Furthermore, an opening 135 is provided in the upper chamber section 111 for introducing a vapor precursor from vapor delivery system 140 into vapor distribution plenum 132. Moreover, temperature control elements 136, such as concentric fluid channels configured to flow a cooled or heated fluid, are provided for controlling the temperature of the vapor distribution system 130, and thereby prevent the decomposition of the metal precursor inside the vapor distribution system 130. For instance, a fluid, such as water, can be supplied to the fluid channels from a vapor distribution temperature control system 138. The vapor distribution temperature control system 138 can include a fluid source, a heat exchanger, one or more temperature sensors for measuring the fluid temperature or vapor distribution plate temperature or both, and a controller configured to control the temperature of the vapor distribution plate 131 from about 20° C. to about 100° C.

As illustrated in FIG. 2, a metal precursor evaporation system 150 is configured to hold a metal precursor 152 and evaporate (or sublime) the metal precursor 152 by elevating the temperature of the metal precursor. A precursor heater 154 is provided for heating the metal precursor 152 to maintain the metal precursor 152 at a temperature that produces a desired vapor pressure of metal precursor 152. The precursor heater 154 is coupled to an evaporation temperature control system 156 configured to control the temperature of the metal precursor 152. For example, the precursor heater 154 can be configured to adjust the temperature of the metal precursor 152 (or evaporation temperature) to be greater than or equal to approximately 40° C. Alternatively, the evaporation temperature is elevated to be greater than or equal to approximately 50° C. For example, the evaporation temperature is elevated to be greater than or equal to approximately 60° C. In one embodiment, the evaporation temperature is elevated to range from approximately 60-150° C., and in another embodiment, to range from approximately 60-90° C.

As the metal precursor 152 is heated to cause evaporation (or sublimation), a carrier gas can be passed over the metal precursor, by the metal precursor, or through the metal precursor, or any combination thereof. The carrier gas can include, for example, an inert gas, such as a noble gas (i.e., He, Ne, Ar, Kr, Xe), or a monoxide, such as CO, for use with metal-carbonyls, or a mixture thereof. For example, a carrier gas supply system 160 is coupled to the metal precursor evaporation system 150, and it is configured to, for instance, supply the carrier gas beneath the metal precursor, or above the metal precursor. Although not shown in FIG. 2, carrier gas supply system 160 can also or alternatively be coupled to the vapor delivery system 140 to supply the carrier gas to the vapor of the metal precursor 152 as or after it enters the vapor delivery system 140. The carrier gas supply system 160 can comprise a gas source 161, one or more control valves 162, one or more filters 164, and a mass flow controller 165. For instance, the flow rate of carrier gas can range from approximately 5 sccm (standard cubic centimeters per minute) to approximately 1000 sccm. In one embodiment, the flow rate of carrier gas can range from about 10 sccm to about 200 sccm. In another embodiment, the flow rate of carrier gas can range from about 20 sccm to about 100 sccm.

Additionally, a sensor 166 is provided for measuring the total gas flow from the metal precursor evaporation system 150. The sensor 166 can, for example, comprise a mass flow controller, and the amount of metal precursor delivered to the process chamber 110 can be determined using sensor 166 and mass flow controller 165. Alternately, the sensor 166 can comprise a light absorption sensor to measure the concentration of the metal precursor in the gas flow to the process chamber 110.

A bypass line 167 can be located downstream from sensor 166, and it can connect the vapor delivery system 140 to an exhaust line 116. Bypass line 167 is provided for evacuating the vapor delivery system 140, and for stabilizing the supply of the metal precursor to the process chamber 110. In addition, a bypass valve 168, located downstream from the branching of the vapor delivery system 140, is provided on bypass line 167.

Referring still to FIG. 2, the vapor delivery system 140 comprises a high conductance vapor line having first and second valves 141 and 142 respectively. Additionally, the vapor delivery system 140 can further comprise a vapor line temperature control system 143 configured to heat the vapor delivery system 140 via heaters (not shown). The temperatures of the vapor lines can be controlled to avoid condensation of the metal precursor in the vapor line. The temperature of the vapor lines can be greater than or equal to 40° C. Additionally, the temperature of the vapor lines can be controlled from about 40° C. to about 150° C., or from about 40° C. to about 90° C. For example, the vapor line temperature can be set to a value approximately equal to or greater than the evaporation temperature.

Moreover, dilution gases can be supplied from a dilution gas supply system 190. The dilution gas can include, for example, an inert gas, such as a noble gas (i.e., He, Ne, Ar, Kr, Xe), or a monoxide, such as CO, for use with metal-carbonyls, or a mixture thereof. For example, the dilution gas supply system 190 is coupled to the vapor delivery system 140, and it is configured to, for instance, supply the dilution gas to vapor metal precursor. The dilution gas supply system 190 can comprise a gas source 191, one or more control valves 192, one or more filters 194, and a mass flow controller 195. For instance, the flow rate of carrier gas can range from approximately 5 sccm (standard cubic centimeters per minute) to approximately 1000 sccm.

Mass flow controllers 165 and 195, and valves 162, 192, 168, 141, and 142 are controlled by controller 196, which controls the supply, shutoff, and the flow of the carrier gas, the metal precursor vapor, and the dilution gas. Sensor 166 is also connected to controller 196 and, based on output of the sensor 166, controller 196 can control the carrier gas flow through mass flow controller 165 to obtain the desired metal precursor flow to the process chamber 110.

Furthermore, as described above, and as shown in FIG. 2, an in-situ cleaning system 170 is coupled to the precursor delivery system 105 of deposition system 100 through cleaning valve 172. At a minimum, the in-situ cleaning system 170 is coupled to the vapor delivery system 140 adjacent the metal precursor evaporation system 150, for example, upstream of first valve 141 and/or sensor 166. The in-situ cleaning system 170 can, for example, comprise a radical generator configured to introduce chemical radical capable of chemically reacting and removing such residue. Additionally, for example, the in-situ cleaning system 170 can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), CIF₃, O₃, XeF₂, or C₃F₈ (or, more generally, CₓF_{y}), respectively. The radical generator can include an Astron® reactive gas generator, commercially available from MKS Instruments, Inc., ASTeX® Products (90 Industrial Way, Wilmington, Mass. 01887).

As illustrated in FIG. 2, the exhaust line 116 connects exhaust chamber 113 to pumping system 118. A vacuum pump 119 is used to evacuate process chamber 110 to the desired degree of vacuum, and to remove gaseous species from the process chamber 110 during processing. An automatic pressure controller (APC) 115 and a trap 117 can be used in series with the vacuum pump 119. The vacuum pump 119 can include a turbo-molecular pump (TMP) capable of a pumping speed up to 5000 liters per second (and greater). Alternately, the vacuum pump 119 can include a dry roughing pump. During processing, the carrier gas, dilution gas, or metal precursor vapor, or any combination thereof can be introduced into the process chamber 110, and the chamber pressure can be adjusted by the APC 115. For example, the chamber pressure can range from approximately 1 mTorr to approximately 500 mTorr, and in a further example, the chamber pressure can range from about 5 mTorr to 50 mTorr. The APC 115 can comprise a butterfly-type valve or a gate valve. The trap 117 can collect unreacted precursor material, and by-products from the process chamber 110.

Referring back to the substrate holder 120 in the process chamber 110, as shown in FIG. 2, three substrate lift pins 127 (only two are shown) are provided for holding, raising, and lowering the substrate 125. The substrate lift pins 127 are coupled to plate 123, and can be lowered to below to the upper surface of substrate holder 120. A drive mechanism 129 utilizing, for example, an air cylinder provides means for raising and lowering the plate 123. Substrate 125 can be transferred into and out of process chamber 110 through gate valve 200 and chamber feed-through passage 202 via a robotic transfer system (not shown), and received by the substrate lift pins 127. Once the substrate 125 is received from the transfer system, it can be lowered to the upper surface of the substrate holder 120 by lowering the substrate lift pins 127.

Referring again to FIG. 2, a controller 180 includes a microprocessor, a memory, and a digital I/O port capable of generating control voltages sufficient to communicate and activate inputs of the processing system 100 as well as monitor outputs from the processing system 100. Moreover, the processing system controller 180 is coupled to and exchanges information with process chamber 110; precursor delivery system 105, which includes controller 196, vapor line temperature control system 143, and evaporation temperature control system 156; vapor distribution temperature control system 138; vacuum pumping system 118; and substrate holder temperature control system 128. In the vacuum pumping system 118, the controller 180 is coupled to and exchanges information with the automatic pressure controller 115 for controlling the pressure in the process chamber 110. A program stored in the memory is utilized to control the aforementioned components of deposition system 100 according to a stored process recipe. One example of processing system controller 180 is a DELL PRECISION WORKSTATION 610™, available from Dell Corporation, Dallas, Tex. The controller 180 may also be implemented as a general-purpose computer, digital signal process, etc.

Controller 180 may be locally located relative to the deposition system 100, or it may be remotely located relative to the deposition system 100 via an internet or intranet. Thus, controller 180 can exchange data with the deposition system 100 using at least one of a direct connection, an intranet, or the internet. Controller 180 may be coupled to an intranet at a customer site (i.e., a device maker, etc.), or coupled to an intranet at a vendor site (i.e., an equipment manufacturer). Furthermore, another computer (i.e., controller, server, etc.) can access controller 180 to exchange data via at least one of a direct connection, an intranet, or the internet.

As described above, for example, conventional systems have contemplated operating the metal precursor evaporation system, as well as the vapor delivery system, within a temperature range of approximately 40-45° C. for ruthenium carbonyl in order to limit metal vapor precursor decomposition and metal vapor precursor condensation. However, due to the low vapor pressure of metal-carbonyls, such as ruthenium carbonyl or rhenium carbonyl, at this temperature, the deposition rate of, for example, ruthenium or rhenium, is very low. In order to improve the deposition rate, the evaporation temperature is raised above about 40° C., for example above about 50° C. Following high temperature evaporation of the metal precursor for one or more substrates, the deposition system is periodically cleaned to remove residues formed on interior surfaces of the deposition system, in particular, on interior surfaces of the vapor delivery system and process chamber.

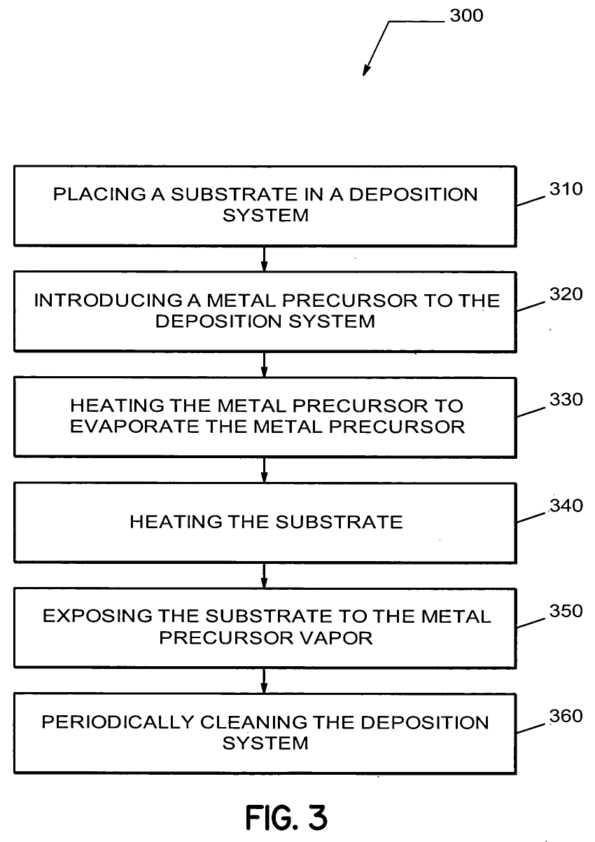

Referring now to FIG. 3, a method of depositing a refractory metal film on a substrate is described. A flow chart 300 is used to illustrate the steps in depositing the metal film in a deposition system in accordance with the method of the present invention. The metal film deposition begins in 310 with placing a substrate in the deposition system for forming the metal film on the substrate. For example, the deposition system can include any one of the depositions systems described above in FIGS. 1 and 2. The deposition system can include a process chamber for facilitating the deposition process, and a substrate holder coupled to the process chamber and configured to support the substrate. Then, in 320, a metal precursor is introduced to the deposition system. For instance, the metal precursor is introduced to a metal precursor evaporation system coupled to the process chamber via a vapor delivery system. Additionally, for instance, the vapor deliver system can be heated.

In 330, the metal precursor is heated to form a metal precursor vapor. The metal precursor vapor can then be transported to the process chamber through the vapor delivery system. In 340, the substrate is heated to a substrate temperature sufficient to decompose the metal precursor vapor, and, in 350, the substrate is exposed to the metal precursor vapor. Steps 310 to 350 may be repeated successively a desired number of times to deposit a metal film on a desired number of substrates.

Following the deposition of the refractory metal film on one or more substrates, the deposition system is periodically cleaned in 360 by introducing a cleaning composition from an in-situ cleaning system coupled to the deposition system, in particular, to the vapor delivery system. The cleaning composition can, for example, include a halogen containing radical, fluorine radical, oxygen radical, ozone, or a combination thereof. The in-situ cleaning system can, for example, include a radical generator, or an ozone generator. When a cleaning process is performed, a “dummy” substrate can be utilized to protect the substrate holder. Furthermore, the metal precursor evaporation system, the vapor delivery system, the process chamber, the vapor distribution system, or the substrate holder, or any combination thereof can be heated.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A deposition system for forming a refractory metal film on a substrate comprising:
a process chamber having a substrate holder configured to support said substrate and heat said substrate, a vapor distribution system configured to introduce metal precursor vapor above said substrate, and a pumping system configured to evacuate said process chamber;
a metal precursor evaporation system configured to evaporate a metal precursor;
a vapor delivery system having a first end coupled to an outlet of said metal precursor evaporation system and a second end coupled to an inlet of said vapor distribution system of said process chamber;
a carrier gas supply system coupled to at least one of said metal precursor evaporation system or said vapor delivery system, or both, and configured to supply a carrier gas to transport said metal precursor vapor in said carrier gas through said vapor delivery system to said inlet of said vapor distribution system; and
an in-situ cleaning system coupled to said vapor delivery system adjacent said outlet of said metal precursor evaporation system and configured to provide a cleaning composition to said vapor delivery system and said process chamber, wherein said cleaning composition is configured to remove residue formed on interior surfaces of said vapor delivery system and said process chamber.

2. The deposition system of claim 1, wherein said substrate holder is configured to heat said substrate to a substrate temperature greater than or equal to 100° C.

3. The deposition system of claim 1, wherein said metal precursor evaporation system is configured to heat said metal precursor to an evaporation temperature greater than or equal to approximately 40° C.

4. The deposition system of claim 1, wherein said vapor delivery system is configured to heat a vapor line therein to a temperature greater than or equal to approximately 40° C.

5. The deposition system of claim 1, further comprising:
a controller coupled to said process chamber, said vapor delivery system, and said metal precursor evaporation system, and configured to perform at least one of setting, monitoring, adjusting, or controlling one or more of a substrate temperature, an evaporation temperature, a vapor line temperature, a flow rate of said carrier gas, or a pressure in said process chamber.

6. The deposition system of claim 5, wherein said controller is further coupled to said in-situ cleaning system, and configured to perform at least one of setting, monitoring, adjusting, or controlling one or more of a flow rate of said cleaning composition or a pressure of said process chamber.

7. The deposition system of claim 1, wherein said metal precursor evaporation system is configured to evaporate a solid metal precursor.

8. The deposition system of claim 1, wherein said metal precursor evaporation system is configured to evaporate a metal-carbonyl precursor.

9. The deposition system of claim 1, wherein said in-situ cleaning system is configured to provide a cleaning composition comprising a halogen-containing radical.

10. The deposition system of claim 1, wherein said in-situ cleaning system is configured to provide a cleaning composition comprising fluorine radical.

11. The deposition system of claim 1, wherein said in-situ cleaning system is configured to provide a cleaning composition comprising oxygen radical.

12. The deposition system of claim 1, wherein said in-situ cleaning system is configured to provide a cleaning composition comprising ozone.

13. The deposition system of claim 1, wherein said in-situ cleaning system comprises one or more of a radical generator or an ozone generator.

14. The deposition system of claim 1, wherein said in-situ cleaning system comprises a radical generator configured to dissociate O₂, CIF₃, NF₃, O₃, or C₃F₈, or any combination thereof.

15. The deposition system of claim 1, wherein said carrier gas supply system is configured to supply an inert gas.

16. The deposition system of claim 1, wherein said vapor delivery system is characterized by a high conductance in excess of about 50 liters/second.

17. The deposition system of claim 1, wherein said residue comprises metal precursor, decomposed metal precursor, or metal.

18. A method for depositing a refractory metal film comprising:
(a) depositing said refractory metal film on a desired number of substrates in succession using a deposition system configured to perform thermal chemical vapor deposition (TCVD) from a metal precursor, wherein said depositing said refractory metal film on each of the desired number of substrates comprises:
placing one substrate of said desired number of substrates in said deposition system, said deposition system having a process chamber configured to deposit said refractory metal film on said one substrate, and a substrate holder coupled to said process chamber and configured to support said one substrate,
introducing a metal precursor to a metal precursor evaporation system coupled to said process chamber via a vapor delivery system,
heating said metal precursor in said metal precursor evaporation system to form a metal precursor vapor,
transporting said metal precursor vapor from said metal precursor evaporation system, through said vapor delivery system, to said process chamber,
heating said one substrate to a substrate temperature sufficient to decompose said metal precursor vapor, and
exposing said one substrate to said metal precursor vapor; and
(b) cleaning said vapor delivery system and said process chamber following said depositing of said refractory metal film on said desired number of substrates by introducing a cleaning composition formed in an in-situ cleaning system to said vapor delivery system adjacent said metal precursor evaporation system and flowing said cleaning composition through said vapor delivery system and into said process chamber.

19. The method of claim 18, wherein said depositing said refractory metal film includes depositing ruthenium.

20. The method of claim 18, wherein said depositing said refractory metal film includes depositing rhenium.

21. The method of claim 18, wherein said introducing said metal precursor comprises introducing a solid metal precursor.

22. The method of claim 18, wherein said introducing said metal precursor comprises introducing a metal-carbonyl.

23. The method of claim 18, wherein said introducing said metal precursor comprises introducing ruthenium carbonyl (Ru₃(CO)₁₂).

24. The method of claim 18, wherein said introducing said metal precursor comprises introducing rhenium carbonyl (Re₂(CO)₁₀).

25. The method of claim 18, wherein said heating said one substrate includes heating to a substrate temperature greater than or equal to about 100° C.

26. The method of claim 18, wherein said heating said metal precursor includes heating to an evaporation temperature greater than or equal to about 40° C.

27. The method of claim 26, wherein said heating said metal precursor includes heating to an evaporation temperature greater than or equal to about 50° C.

28. The method of claim 26, wherein said heating said metal precursor includes heating to an evaporation temperature ranging from about 50° C. to about 150° C.

29. The method of claim 26, wherein said heating said metal precursor includes heating to an evaporation temperature ranging from about 60° C. to about 90° C.

30. The method of claim 18, wherein said cleaning includes using a radical generator to introduce chemical radicals to said cleaning composition.

31. The method of claim 30, wherein said radical generator introduces one or more of fluorine radical or oxygen radical to said cleaning composition.

32. The method of claim 31, wherein said cleaning includes using an ozone generator to introduce a partial pressure of ozone to said cleaning composition.

33. The method of claim 18, wherein said cleaning includes using an ozone generator to introduce a partial pressure of ozone to said cleaning composition.

34. The method of claim 18, wherein said introducing said metal precursor comprises introducing one of W(CO)₆, Mo(CO)₆, Co₂(CO)₈, Rh₄(CO)₁₂, Cr(CO)₆, or Os₃(CO)₁₂.
